(19) United States
(12) Patent Application Publication
(10) Pub. No.: US 2026/0114006 A1
(43) Pub. Date: Apr. 23, 2026

(54) SEMICONDUCTOR DEVICE WITH TRIMMED GATE SPACER

(71) Applicant: International Business Machines Corporation, Armonk, NY (US)

(72) Inventors: Fabio Carta, Pleasantville, NY (US); Erik Milosevic, Schenectady, NY (US); Tao Li, Slingerlands, NY (US); Ruilong Xie, Niskayuna, NY (US)

(21) Appl. No.: 18/924,321

(22) Filed: Oct. 23, 2024

(51) Int. Cl. H01L 29/66; H01L 29/06; H01L 29/417; H01L 29/423; H01L 29/775; H01L 29/786

(52) U.S. Cl. CPC H10D 64/015; H10D 30/43; H10D 30/6729; H10D 30/6735; H10D 30/6757; H10D 62/121; H10D 64/018; H10D 30/014

(57) ABSTRACT

Embodiments comprise a semiconductor device that includes a gate electrode formed on a substrate, a source/drain epitaxial layer formed on the substrate, a gate spacer layer formed on sides of the gate electrode, and a source/drain spacer layer formed on sides of the source/drain epitaxial layer. The source/drain spacer layer has a first width, and the gate spacer layer has a second width that is less than the first width.

### BACKGROUND

The present disclosure relates to fabrication methods and resulting structures for semiconductor devices. More specifically, the present disclosure relates to fabrication methods and resulting structures for semiconductor devices including a thinned/trimmed gate spacer.

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. As semiconductor integrated circuits (ICs) and/or chips become smaller, the implementation of stacked nanosheets in semiconductor devices has increased.

### SUMMARY

Embodiments of the present disclosure relate to a semiconductor device. The semiconductor device includes a gate electrode formed on a substrate, a source/drain epitaxial layer formed on the substrate, a gate spacer layer formed on sides of the gate electrode, and a source/drain spacer layer formed on sides of the source/drain epitaxial layer. The source/drain spacer layer has a first width, and the gate spacer layer has a second width that is less than the first width.

Embodiments of the present disclosure relate to an electronic device including a semiconductor device. The semiconductor device includes a gate electrode formed on a substrate, a source/drain epitaxial layer formed on the substrate, a gate spacer layer formed on sides of the gate electrode, and a source/drain spacer layer formed on sides of the source/drain epitaxial layer. The source/drain spacer layer has a first width, and the gate spacer layer has a second width that is less than the first width.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A is a partial cross-sectional view of a semiconductor device at an intermediate stage of the fabrication process and taken along the X1-X2 line of FIG. 1C, according to embodiments.

FIG. 1B is a partial cross-sectional view of the semiconductor device at an intermediate stage of the fabrication process and taken along the Y1-Y2 line of FIG. 1C, according to embodiments.

FIG. 1C is a simplified top view of the semiconductor device shown in FIGS. 1A and 1B, according to embodiments.

FIG. 2A is a partial cross-sectional view of the semiconductor device of FIG. 1A at a subsequent stage of the fabrication process and taken along the X1-X2 line of FIG. 1C, according to embodiments.

FIG. 2B is a partial cross-sectional view of the semiconductor device of FIG. 1B at a subsequent stage of the fabrication process and taken along the Y1-Y2 line of FIG. 1C, according to embodiments.

FIG. 3A is a partial cross-sectional view of the semiconductor device of FIG. 2A at a subsequent stage of the fabrication process and taken along the X1-X2 line of FIG. 1C, according to embodiments.

FIG. 3B is a partial cross-sectional view of the semiconductor device of FIG. 2B at a subsequent stage of the fabrication process and taken along the Y1-Y2 line of FIG. 1C, according to embodiments.

FIG. 4A is a partial cross-sectional view of the semiconductor device of FIG. 3A at a subsequent stage of the fabrication process and taken along the X1-X2 line of FIG. 1C, according to embodiments.

FIG. 4B is a partial cross-sectional view of the semiconductor device of FIG. 3B at a subsequent stage of the fabrication process and taken along the Y1-Y2 line of FIG. 1C, according to embodiments.

FIG. 5A is a partial cross-sectional view of the semiconductor device of FIG. 4A at a subsequent stage of the fabrication process and taken along the X1-X2 line of FIG. 1C, according to embodiments.

FIG. 5B is a partial cross-sectional view of the semiconductor device of FIG. 4B at a subsequent stage of the fabrication process and taken along the Y1-Y2 line of FIG. 1C, according to embodiments.

FIG. 6A is a partial cross-sectional view of the semiconductor device of FIG. 5A at a subsequent stage of the fabrication process and taken along the X1-X2 line of FIG. 1C, according to embodiments.

FIG. 6B is a partial cross-sectional view of the semiconductor device of FIG. 5B at a subsequent stage of the fabrication process and taken along the Y1-Y2 line of FIG. 1C, according to embodiments.

FIG. 7A is a partial cross-sectional view of the semiconductor device of FIG. 6A at a subsequent stage of the fabrication process and taken along the X1-X2 line of FIG. 1C, according to embodiments.

FIG. 7B is a partial cross-sectional view of the semiconductor device of FIG. 6B at a subsequent stage of the fabrication process and taken along the Y1-Y2 line of FIG. 1C, according to embodiments.

FIG. 8A is a partial cross-sectional view of the semiconductor device of FIG. 7A at a subsequent stage of the fabrication process and taken along the X1-X2 line of FIG. 1C, according to embodiments.

FIG. 8B is a partial cross-sectional view of the semiconductor device of FIG. 7B at a subsequent stage of the fabrication process and taken along the Y1-Y2 line of FIG. 1C, according to embodiments.

FIG. 9A is a partial cross-sectional view of the semiconductor device of FIG. 8A at a subsequent stage of the fabrication process and taken along the X1-X2 line of FIG. 1C, according to embodiments.

FIG. 9B is a partial cross-sectional view of the semiconductor device of FIG. 8B at a subsequent stage of the fabrication process and taken along the Y1-Y2 line of FIG. 1C, according to embodiments.

FIG. 10A is a partial cross-sectional view of the semiconductor device of FIG. 9A at a subsequent stage of the fabrication process and taken along the X1-X2 line of FIG. 1C, according to embodiments.

FIG. 10B is a partial cross-sectional view of the semiconductor device of FIG. 9B at a subsequent stage of the fabrication process and taken along the Y1-Y2 line of FIG. 1C, according to embodiments.

### DETAILED DESCRIPTION

The present disclosure describes semiconductor devices including a gate spacer structure that includes trimmed (or thinned) portions that enable a robust source/drain confinement and improved canyon space between adjacent gates. For semiconductor devices with a small active region (RX) pitch, one way to isolate the source/drain (S/D) regions and also prevent electrical shorting between neighboring devices is to use a spacer to confine the epitaxial growth from the sides. This spacer may be formed with a deposition process followed by a breakthrough process. However, when the spacer is too thin and/or has a high aspect ratio of height to width, they may fall down (or topple over) and cause a defect (e.g., electrical shorting) after the S/D recessing operation. However, if the spacer is too thick, then the canyon space between adjacent gates may be too small which may also cause an inner spacer pinch off at small active region widths. A thicker spacer may also cause other difficulties during S/D formation processing.

However, in the present embodiments, a semiconductor device is provided with a gate spacer trimming (or thinning) scheme that thins a portion of the spacer in the gate region while keeping the thickness of a portion of the spacer in the source/drain region the same, and this may help to address the issues discussed above. This may enable a robust source/drain confinement and improved canyon space between adjacent gates.

The flowcharts and cross-sectional diagrams in the Figures illustrate methods of manufacturing semiconductor devices according to various embodiments. In some alternative implementations, the manufacturing steps may occur in a different order than that is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A”and layer “B”are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof relate to the described structures and methods, as oriented in the particular drawing figures. Several of the figures show different orientation such as the top view, and different cross-sectional views. It should be noted that right and left, or top and bottom, etc. relate to (or depend on) the particular view of each figure. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions.

The wafer footprint of a FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions. Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which may aid when continuously scaling gate lengths down to seven nanometer CMOS technology and below.

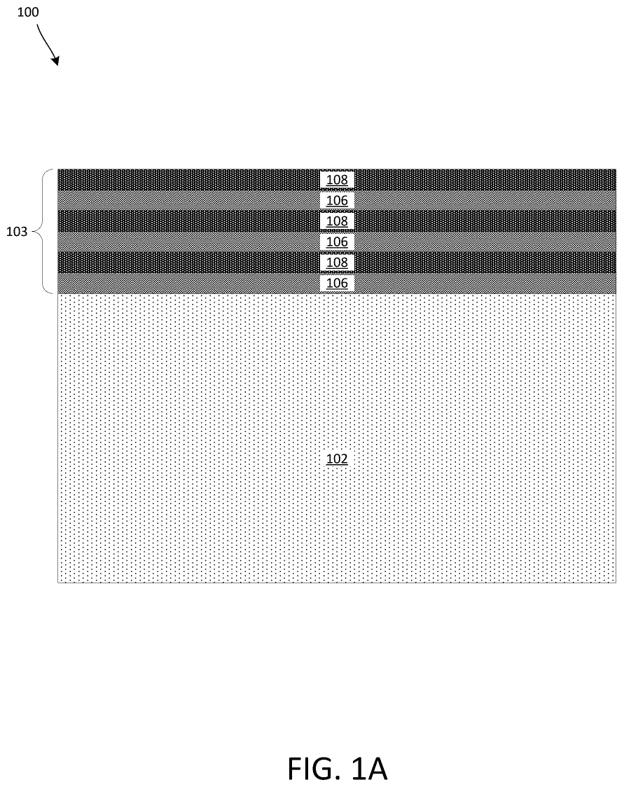

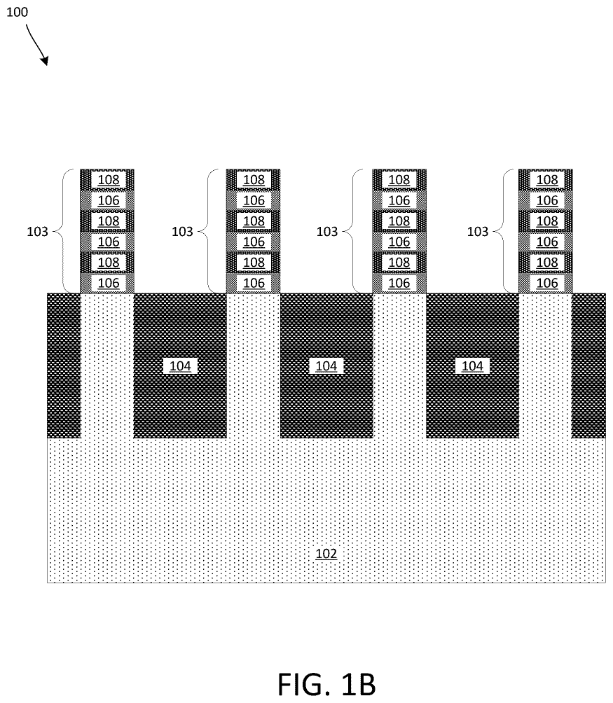

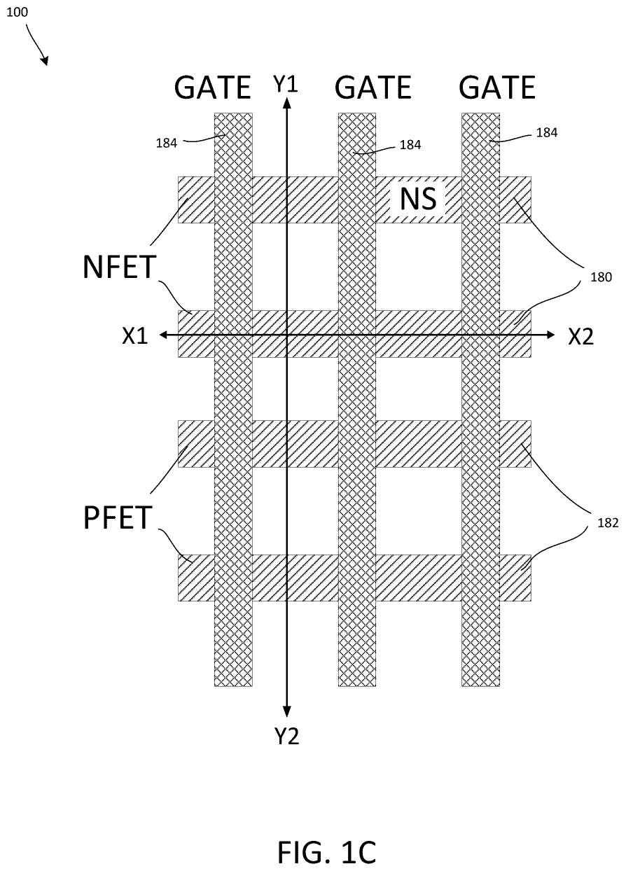

Referring now to the drawings in which like numerals represent the same or similar elements and initially to FIG. 1A, this figure is a partial cross-sectional view of a semiconductor device 100 at an intermediate stage of the fabrication process and taken along the X1-X2 line of FIG. 1C, according to embodiments. As shown in FIG. 1A, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 102 is entirely composed of at least one semiconductor material. It should be appreciated that the substrate 102 may be comprised of any other suitable material(s) than those listed above. The semiconductor device may be incorporated into any suitable electronic device.

Referring again to FIG. 1A, the semiconductor device 100 includes a nanosheet stack 103 formed on the substrate 102. The nanosheet stack 103 initially includes a first sacrificial layer 106 formed on the substrate 102, followed by the formation of a semiconductor layer 108. In an example, the sacrificial layer 106 is composed of silicon-germanium (e.g., Si—Ge, or more generally, where the Ge ranges from about 15-35%). Next, the first (or bottommost) semiconductor layer 108 is formed on an upper surface of the bottommost sacrificial layer 106. In an example, the semiconductor layer 108 is composed of silicon. Several additional layers of the sacrificial layer 106 and the semiconductor layer 108 are alternately formed. It should be appreciated that any suitable number of alternating layers of sacrificial layers 106 and semiconductor layers 108 may be formed.

In certain embodiments, the sacrificial layers 106 have a vertical thickness ranging, for example, from approximately 3 nm to approximately 20 nm. In certain embodiments, the semiconductor layers 108 have a vertical thickness ranging, for example, from approximately 3 nanometers (nm) to approximately 10 nm. Although the range of 3-20 nm is cited as an example range of thickness, other thicknesses of these layers may be used. In certain embodiments, certain of the sacrificial layers 106 and/or the semiconductor layers 108 may have different thicknesses relative to one another. Therefore, multiple epitaxial growth processes can be performed to form the sacrificial layers 106 and the semiconductor layers 108.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP should be of a sufficient value to accommodate the gate stack that will be formed in the spaces created by later removal of the sacrificial layers 106.

Referring now to FIG. 1B, the nanosheet stacks 103 are at stage of the manufacturing process where they have already been patterned using one or more suitable lithography and material removal steps. As shown in FIG. 1B, the patterning is performed on the nanosheet stacks 103, and shallow trench isolation regions 104 are formed into the substrate 102. As shown in detail in FIG. 1B, the shallow trench isolation (STI) regions 104 are formed in the substrate 102 between adjacent nanosheet stacks 103. In general, shallow trench isolation is an integrated circuit feature which prevents electric current leakage between adjacent semiconductor device components. STI is generally used on CMOS process technology nodes of 250 nanometers and smaller. STI regions 104 are created early during the semiconductor device 100 fabrication process before transistors are formed. The steps of the STI process involve etching a pattern of trenches in the silicon, depositing one or more dielectric materials (such as silicon dioxide) to fill the trenches, and removing the excess dielectric using a technique such as chemical-mechanical planarization.

Referring now to FIG. 1C, this figure is a simplified top-down (or plan) view of the semiconductor device 100 shown in FIGS. 1A and 1B, and shows the general locations of the NFET type active regions 180 and the PFET type active regions 182 (sometimes abbreviated as RX) and the gate regions 184 (sometimes abbreviated as PC) of the semiconductor device 100. It should be appreciated that the scale and locations of these various regions are approximations and are merely intended to show where certain components and regions are relative to others from a top-down perspective.

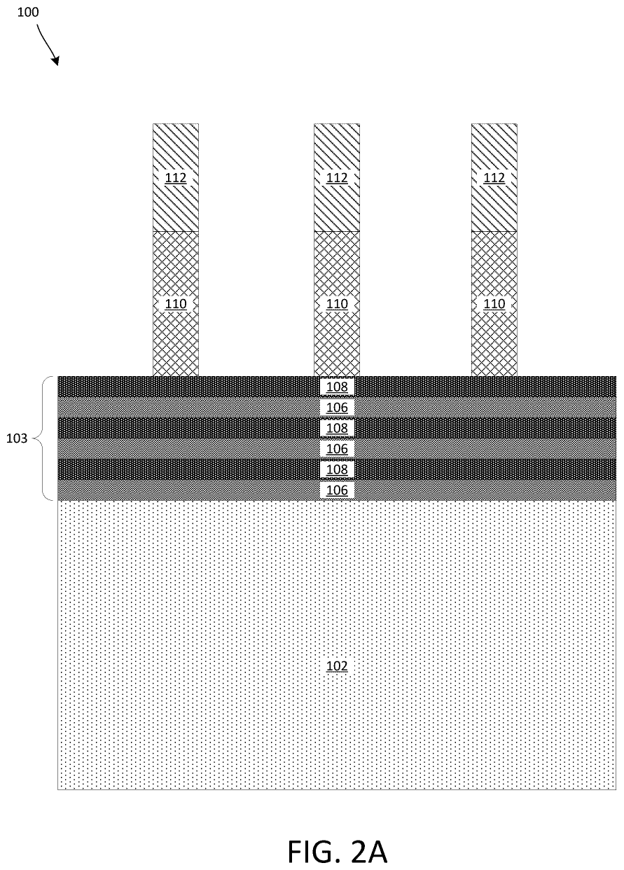

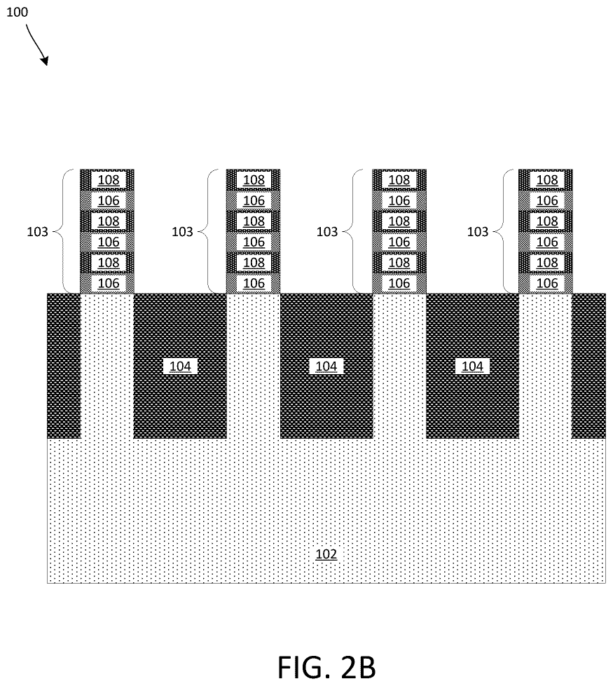

Referring now to FIG. 2A, this figure is a partial cross-sectional view of the semiconductor device 100 of FIG. 1A at a subsequent stage of the fabrication process and taken along the X1-X2 line of FIG. 1C, according to embodiments. Similarly, FIG. 2B is a partial cross-sectional view of the semiconductor device 100 of FIG. 1B at a subsequent stage of the fabrication process and taken along the Y1-Y2 line of FIG. 1C, according to embodiments. As shown in FIG. 2A, a dummy gate 110 (or dummy polycrystalline (PC) layer) is formed on the nanosheet stacks 103. The dummy gate 110 may be formed by any suitable deposition technique known to one of skill in the art. In one example, the dummy gate 110 is formed by depositing a thin SiO₂ dummy gate oxide layer (not shown), followed by depositing a layer of amorphous silicon (a-Si) as the dummy gate 110. In certain examples, the dummy gate 110 may be composed of polycrystalline silicon (poly silicon), amorphous silicon, and/or an oxide, such as, SiO₂. In certain examples, the dummy gate 110 is patterned using the gate hardmask 112 as a mask to perform the patterning. The gate patterning may be performed by first patterning the gate hardmask 112 and then using the patterned gate hardmask to etch the dummy gates 110. Also, as shown in FIG. 2A, a gate hardmask 112 is formed on the dummy gate 110. There are no changes between the view of FIG. 2B and the view of FIG. 1B.

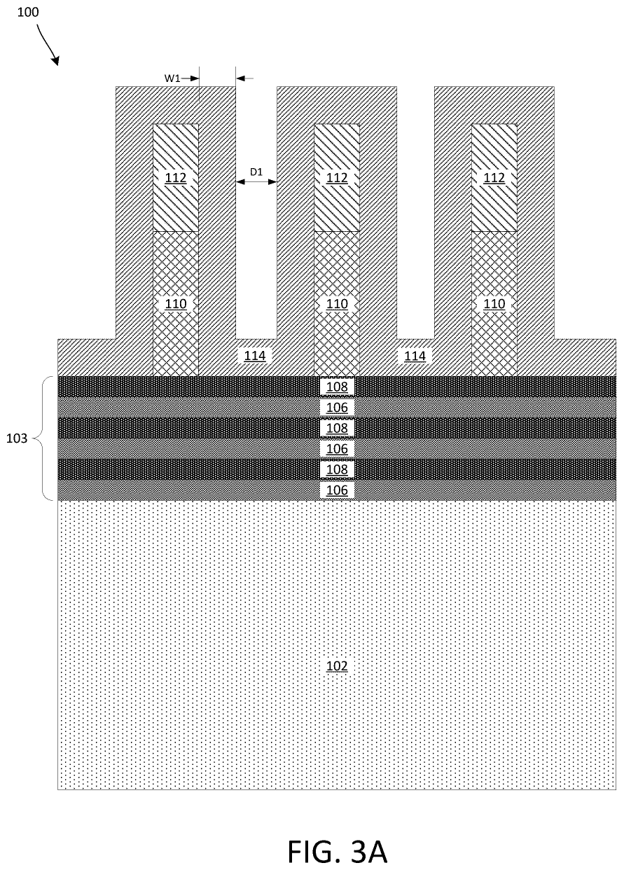

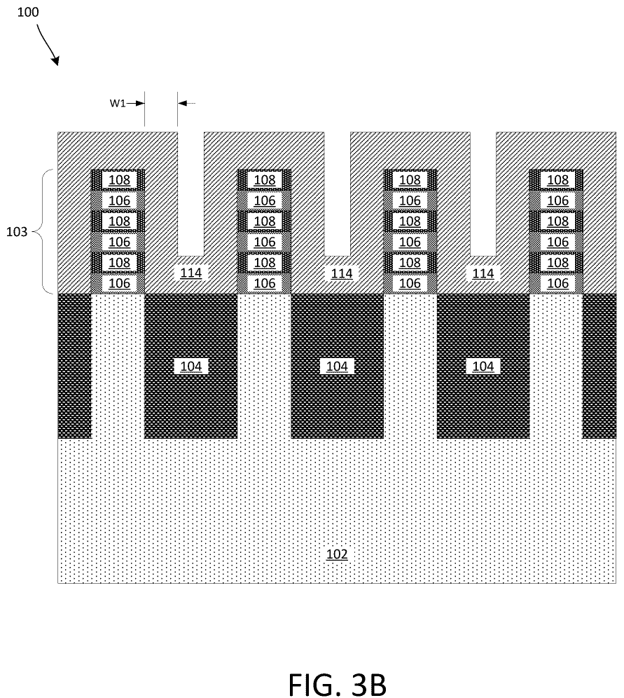

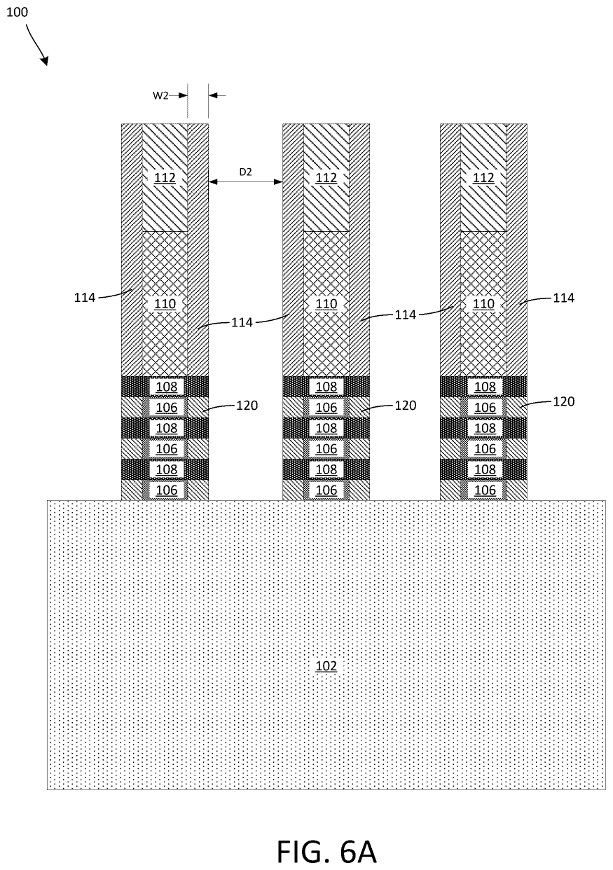

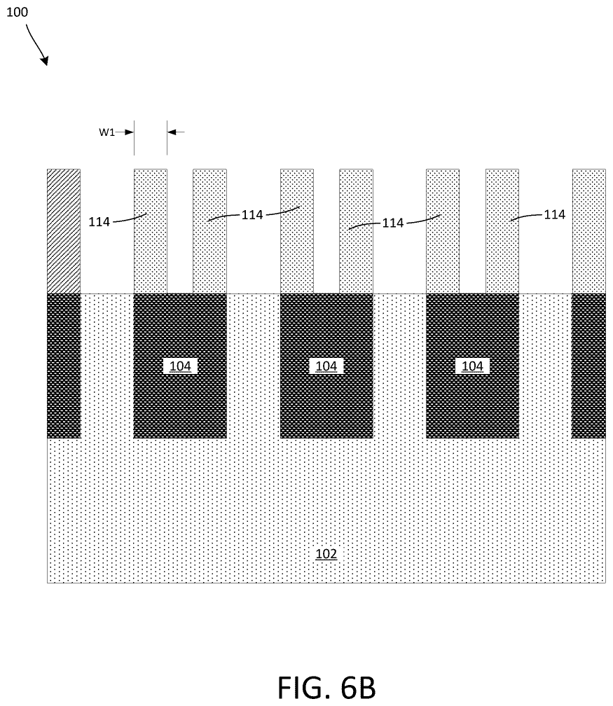

Referring now to FIG. 3A, this figure is a partial cross-sectional view of the semiconductor device 100 of FIG. 2A at a subsequent stage of the fabrication process and taken along the X1-X2 line of FIG. 1C, according to embodiments. Similarly, FIG. 3B is a partial cross-sectional view of the semiconductor device 100 of FIG. 2B at a subsequent stage of the fabrication process and taken along the Y1-Y2 line of FIG. 1C, according to embodiments. As shown in FIGS. 3A and 3B, after the dummy gate 110 is formed, a spacer material is conformally deposited over the semiconductor device 100, forming a spacer layer 114. As shown in FIG. 3A, the spacer layer 114 is formed on top of the nanosheet stack 103 and it also covers both the dummy gate 110 and the gate hardmask 112. As shown in FIG. 3B, the spacer layer 114 initially covers the sidewalls and the top surface of the nanosheet stacks 103. The spacer layer 114 is initially formed to a uniform first thickness W1, as shown in both FIGS. 3A and 3B. This results in a first distance D1 between the sidewalls of the spacer layer 114. Exemplary spacer layer 114 materials may be SiN, SiO₂, a combination of SiN and SiO₂, SiON, SiCN, SiOCN, SiBCN, SiOC, or the like. Spacer layers 114 may be formed by known deposition techniques such as, for example, PVD, CVD, and ALD. It should be appreciated that the portions of the spacer layer 114 appearing in the gate regions shown in FIG. 6A may also be referred to as the gate spacer layer or gate spacer, and the portions of the spacer layer 114 appearing in the source/drain (S/D) regions shown in FIG. 6B may also be referred to as the source/drain spacer layer or S/D spacer, even though the spacer layer 114 may be formed in a single processing operation and may be composed of the same material(s).

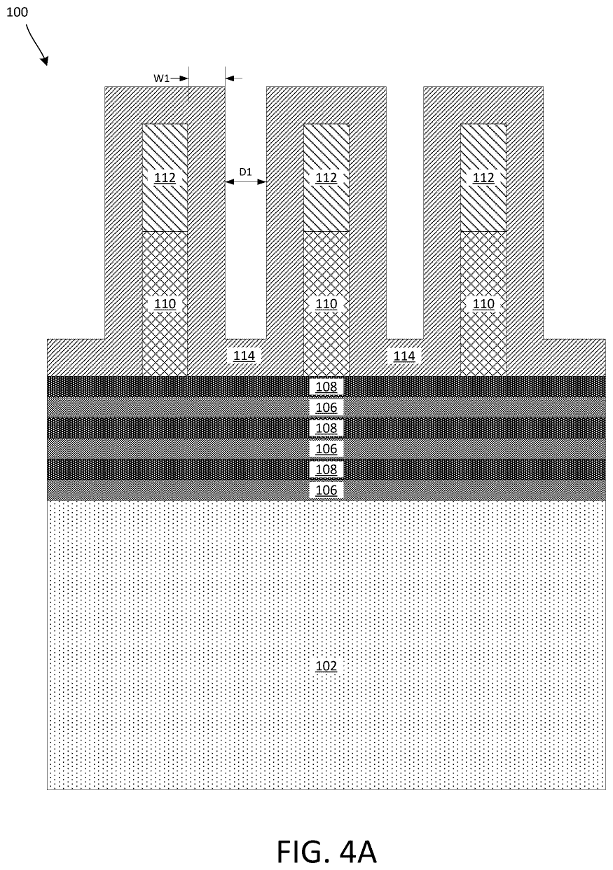

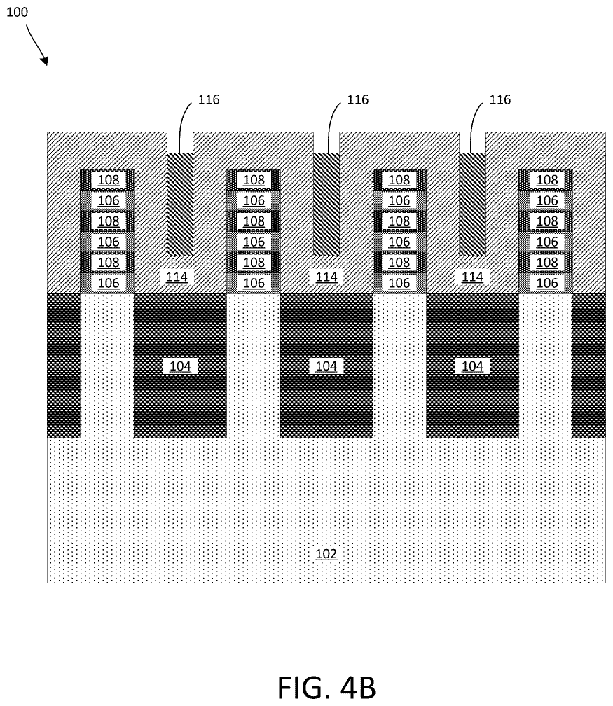

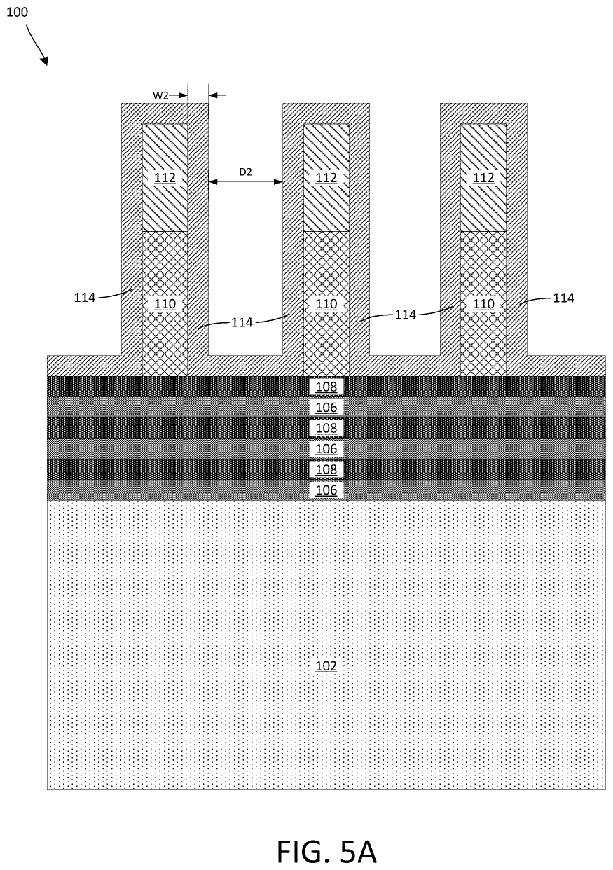

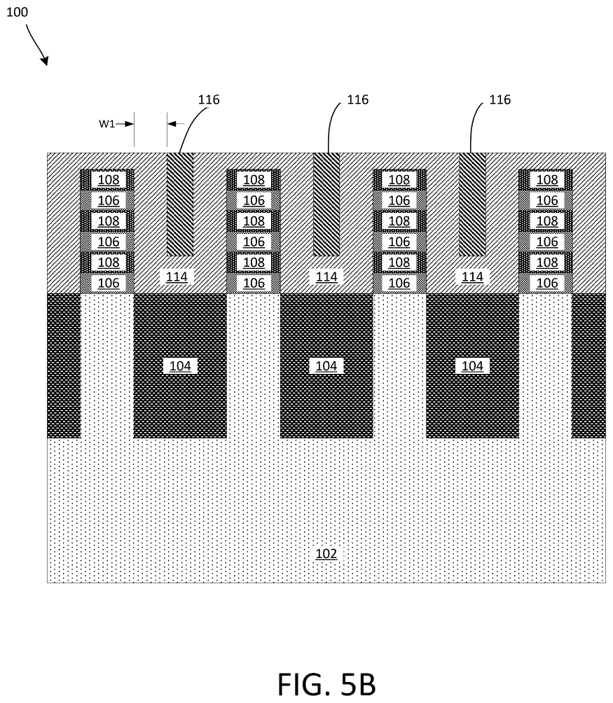

Referring now to FIG. 4A, this figure is a partial cross-sectional view of the semiconductor device 100 of FIG. 3A at a subsequent stage of the fabrication process and taken along the X1-X2 line of FIG. 1C, according to embodiments. Similarly, FIG. 4B is a partial cross-sectional view of the semiconductor device 100 of FIG. 3B at a subsequent stage of the fabrication process and taken along the Y1-Y2 line of FIG. 1C, according to embodiments. As shown in FIG. 4B, an organic planarization layer 116 is formed with any suitable material deposition technique discussed herein. Although not shown in FIGS. 4A and 4B, the organic planarization layer 116 is initially formed to an initial level that is above a top surface of the nanosheet stacks 103 and may be at or above a top surface of the dummy gate 110 and/or the gate hardmask 112. Then, a suitable material removal process is performed to remove a portion of the organic planarization layer 116 so that none of this material remains between the dummy gates 110 or the gate hardmasks 112, as shown in FIG. 4A. Also, as shown in FIG. 4B, the organic planarization layer 116 is partially removed (or etched back) so that a remaining portion of the organic planarization layer 116 still exists between the adjacent nanosheet stacks 103, as shown in FIG. 4B. In certain examples, a top surface of the remaining portion of the organic planarization layer 116 is above a top surface of the nanosheet stacks 103. One purpose of this organic planarization layer 116 is to protect the protect the vertical portions of the spacer layer 114 shown in FIG. 5B during a subsequent material removal step for the spacer layer 114, as discussed below.

Referring now to FIG. 5A, this figure is a partial cross-sectional view of the semiconductor device 100 of FIG. 4A at a subsequent stage of the fabrication process and taken along the X1-X2 line of FIG. 1C, according to embodiments. Similarly, FIG. 5B is a partial cross-sectional view of the semiconductor device 100 of FIG. 4B at a subsequent stage of the fabrication process and taken along the Y1-Y2 line of FIG. 1C, according to embodiments. As shown in FIG. 5A, a suitable material removal process is used to uniformly remove some of the material of the spacer layer 114 from all surfaces thereof to reduce the overall thickness (or width) of the spacer layer 114 to W2 in the areas not covered by the organic planarization layer 116. As such, all portions of the spacer layer 114, as shown in FIG. 5A, have been reduced in thickness from the original first thickness W1 down to a second thickness W2. However, as shown in FIG. 5B, because the organic planarization layer 116 is covering the spacer layer 114 in the source/drain region, the width of the spacer layer 114 in FIG. 5B remains at the first thickness W1. Accordingly, after the material removal process, the spacer layer 114 has a lesser second thickness W2 in the gate region (see, FIG. 5A) and a greater second thickness W1 in the source/drain region. In certain examples, the first width of the source/drain portion of the spacer layer is about 5-8 nm, and the second width of the gate portion of the spacer layer is about 9-15 nm.

Referring now to FIG. 6A, this figure is a partial cross-sectional view of the semiconductor device 100 of FIG. 5A at a subsequent stage of the fabrication process and taken along the X1-X2 line of FIG. 1C, according to embodiments. Similarly, FIG. 6B is a partial cross-sectional view of the semiconductor device 100 of FIG. 5B at a subsequent stage of the fabrication process and taken along the Y1-Y2 line of FIG. 1C, according to embodiments. As shown in FIG. 6B, following the thinning of the spacer layer 114, a suitable material removal process such as, for example, ashing is used to remove the remainder of the organic planarization layer 116. The ashing process may be used to completely remove the organic planarization layer 116 using a suitable reaction gas, for example, O₂, N₂, H₂/N₂, O₃, CF₄, or any combination thereof.

Then, as shown in FIG. 6A, a suitable material removal process is performed to remove the horizontal portions of the spacer layer 114, while leaving the vertical portions thereof intact. Thus, although not shown in FIG. 6B, the nanosheet stacks 103 are exposed in the source/drain region. In addition, a same (or a different) material removal process is used to remove the portions of the nanosheet stacks 103 that are not covered by the dummy gate 110, the gate hardmask 112, or the spacer layer 114. Thus, as shown in FIG. 6B, because the nanosheet stacks 103 were previously exposed they are completely removed down to the level of the substrate 102, thereby removing the sacrificial layers 106 and the semiconductor layers 108 of the nanosheet stacks 103 in this source/drain region. Thus, as also shown in FIG. 6B, the spacer layer 114 with the wider first thickness W1 is all that remains above the substrate 102 and the STI regions 104. Because the spacer layer 114 has the wider first thickness W1 (i.e., relative to the narrowed second thickness W2 shown in FIG. 6A) it is less prone to falling over. As mentioned above when the spacer layer 114 is too thin and/or has a high aspect ratio of height to width, it may fall down (or topple over) and cause a defect (e.g., electrical shorting) after the S/D recessing operation. Referring again to FIG. 6A, after the material removal process is performed, the spacer layer 114 with the second thickness W2 remains only on the sidewalls of the nanosheet stacks 103 in this gate region. Because of the relatively wider second distance D2 between the adjacent gate regions shown in FIG. 6A (due to the prior thinning of the spacer layer 114), the space between adjacent gates is large enough to prevent or reduce pinch off of the inner spacers 120 (see also, FIG. 6A) at small RX widths.

Referring again to FIG. 6A, after the removal of the horizontal portions of the spacer layer 114 and the unprotected portions of the nanosheet stacks 103, the sacrificial layers 106 of the remaining nanosheet stacks 103 in the gate regions are recessed in a horizontal direction, followed by inner spacer 120 formation. A selective etching process using, for example, a boron-based chemistry or a chlorine-based chemistry may be used, which selectively recesses the exposed portions of the sacrificial layers 106 without significantly attacking the surrounding materials (e.g., the semiconductor layers 108, the substrate 102, the gate hardmask 112, or the spacer layer 114). Then, the inner spacers 120 are formed in the indents created by the removal of the portions of the sacrificial layers 106. An optional isotropic etching process may be performed to clean up the edges of the inner spacers 120.

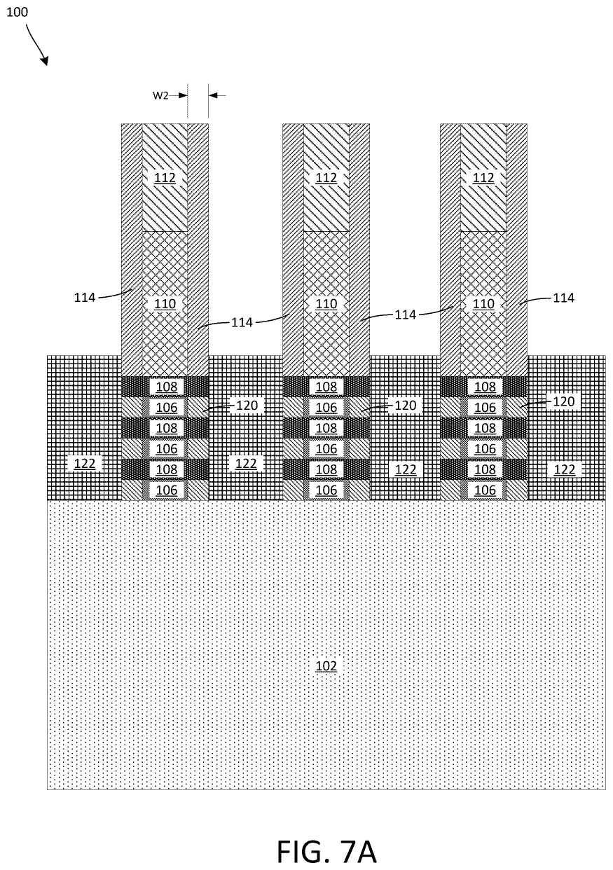

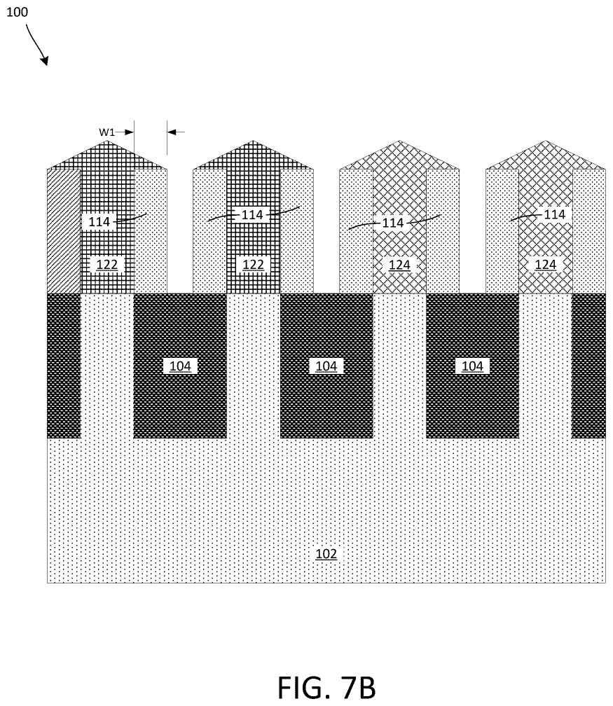

Referring now to FIG. 7A, this figure is a partial cross-sectional view of the semiconductor device 100 of FIG. 6A at a subsequent stage of the fabrication process and taken along the X1-X2 line of FIG. 1C, according to embodiments. Similarly, FIG. 7B is a partial cross-sectional view of the semiconductor device 100 of FIG. 6B at a subsequent stage of the fabrication process and taken along the Y1-Y2 line of FIG. 1C, according to embodiments. As shown in FIGS. 7A and 7B, n-type source/drain epitaxial layers 122 and p-type source/drain epitaxial layers 124 are formed on the substrate 102 between the adjacent nanosheet stacks 103. In certain examples, type source/drain epitaxial layers 122 and p-type source/drain epitaxial layers 124 may be formed to a height that is at or somewhat above an upper surface of the nanosheet stacks 103.

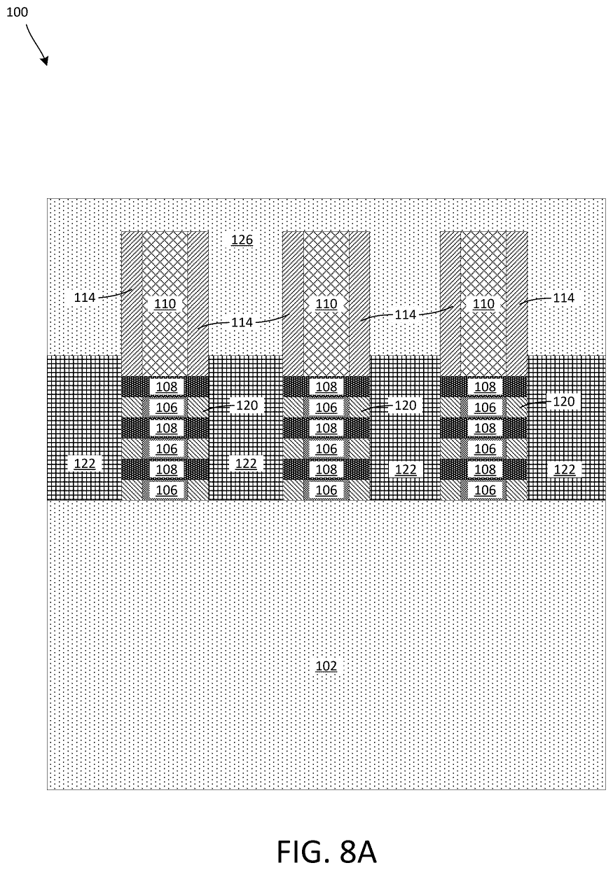

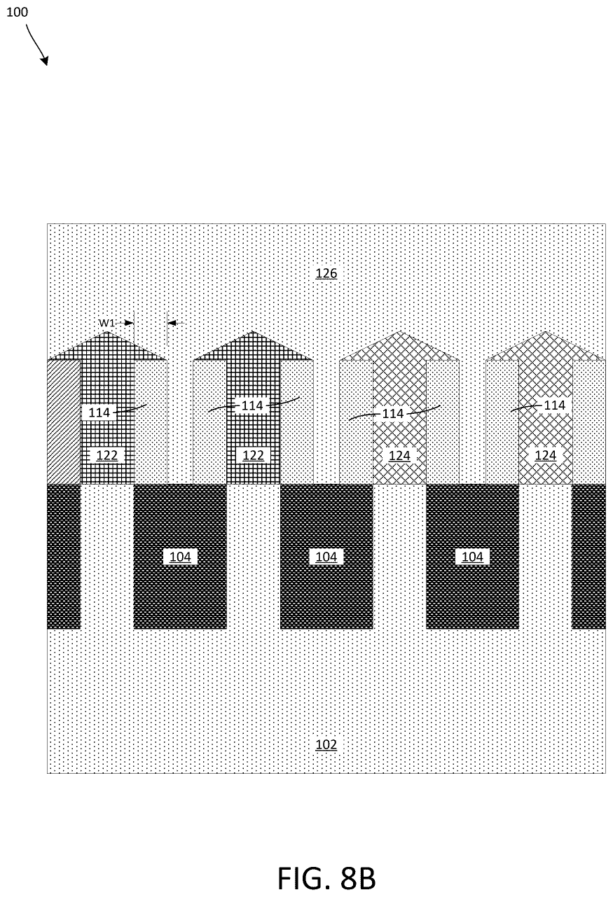

Referring now to FIG. 8A, this figure is a partial cross-sectional view of the semiconductor device 100 of FIG. 7A at a subsequent stage of the fabrication process and taken along the X1-X2 line of FIG. 1C, according to embodiments. Similarly, FIG. 8B is a partial cross-sectional view of the semiconductor device 100 of FIG. 7B at a subsequent stage of the fabrication process and taken along the Y1-Y2 line of FIG. 1C, according to embodiments. As shown in FIGS. 8A and 8B, an interlayer dielectric (ILD) layer 126 is formed over the n-type source/drain epitaxial layers 122 and p-type source/drain epitaxial layers 124. Then, the gate hardmask 112 is removed with a suitable material removal process.

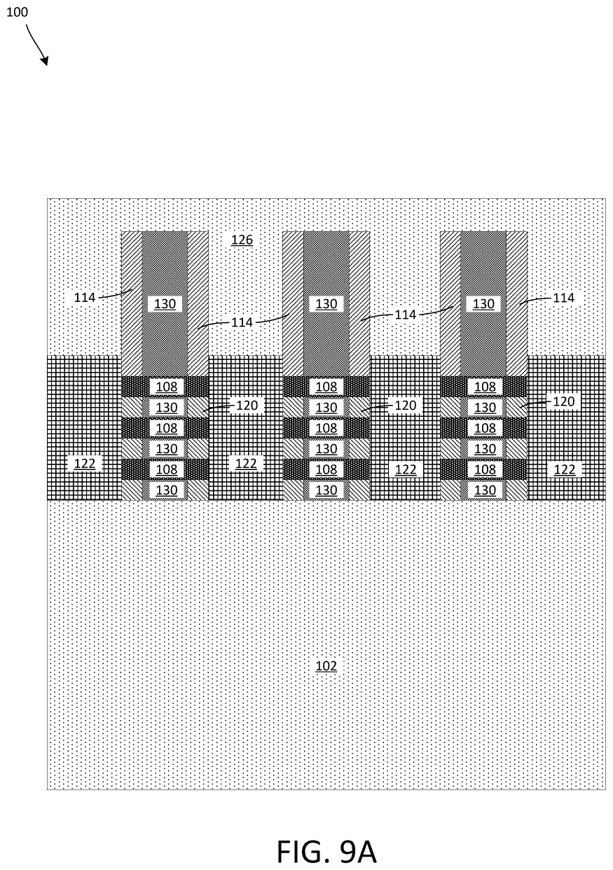

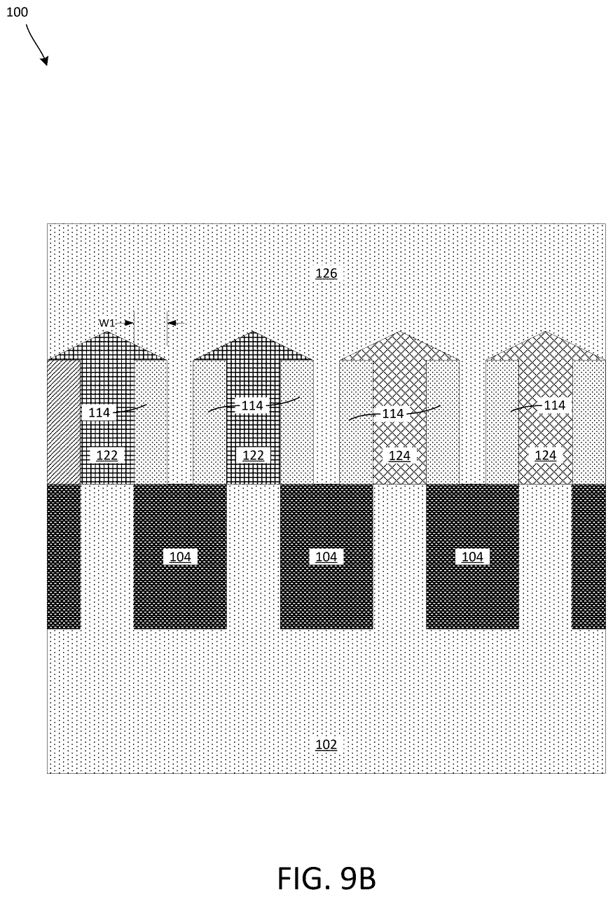

Referring now to FIG. 9A, this figure is a partial cross-sectional view of the semiconductor device 100 of FIG. 8A at a subsequent stage of the fabrication process and taken along the X1-X2 line of FIG. 1C, according to embodiments. Similarly, FIG. 9B is a partial cross-sectional view of the semiconductor device 100 of FIG. 8B at a subsequent stage of the fabrication process and taken along the Y1-Y2 line of FIG. 1C, according to embodiments. As shown in FIG. 9A, a gate cut patterning process is performed (not shown) to selectively remove the dummy gate 110, followed by removal of (or release of) the SiGe material of the sacrificial layers 106. After the material of the sacrificial layers 106 has been released, a high-κ metal gate (HKMG) stack 130 is formed in the spaces created by the previous removal of the SiGe material of the sacrificial layers 106, and the dummy gate 110. In certain embodiments, the forming of the HKMG stack 130 (also referred to as the gate or gate electrode) includes first forming a continuous layer of gate dielectric material (not shown for the sake of simplicity) and then forming a gate electrode metal layer inside the gate opening. The continuous layer of gate dielectric material can include silicon oxide, or a dielectric material having a dielectric constant greater than 4.0 (such dielectric materials can be referred to as a high-κ metal gate dielectric material). Illustrative examples of high-κ gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc, Ta)O₃), and/or lead zinc niobite (Pb(Zn, Nb)O). The HKMG dielectric layer dielectric material can further include dopants such as lanthanum (La), aluminum (Al) and/or magnesium (Mg). The continuous layer of the high-κ metal gate can be formed utilizing a deposition process such as, for example, ALD, CVD, PECVD, or PVD. It should be appreciated that a chemical mechanical planarization (CMP) process can be applied to the top surface.

Referring again to FIGS. 9A and 9B, the gate electrode metal layer of the HKMG stack 130 may include an NFET work function metal (WFM) material or a PFET WFM material, which is deposited in the spaces created by the previous removal of the sacrificial layers 106 in the nanosheet stack 103. Thus, in certain examples, the gate electrode (or HKMG stack 130) includes a high-κ dielectric layer (not shown), and the work function metal layer in contact with the high-κ dielectric layer. In the cross-sectional view of FIG. 9A, the HKMG stack 130 may include the NFET WFM layer to correspond with the adjacent n-type source/drain epitaxial layers 122. The different WFM layers form the overall HKMG stack 130 structures. The layer of WFM can be used to set a threshold voltage of the FET to a desired value. In some embodiments, the layer of WFM can be selected to effectuate an n-type threshold voltage shift. “N-type threshold voltage shift” as used herein means a shift in the effective work-function of the work-function metal-containing material towards a conduction band of silicon in a silicon-containing material. In solid-state physics, the work function is the minimum thermodynamic work (i.e., energy) needed to remove an electron from a solid to a point in the vacuum immediately outside the solid surface. Also, this energy (work function) is a measure of how firmly a particular metal holds its electrons. In general, the conduction band is the range of permissible energy values which an electron in a solid material can have that allows the electron to dissociate from a particular atom and become a free charge carrier in the material. In one embodiment, the work function of the n-type work function metal ranges from approximately 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the layer of WFM can be selected to effectuate a p-type threshold voltage shift. In one embodiment, the work function of the p-type work function metal ranges from approximately 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. In general, the valence band is the range of permissible energy values that are the highest energies an electron can have and still be associated with a particular atom of a solid material. Examples of such materials that can effectuate a p-type threshold voltage shift include, but are not limited to, titanium nitride, and tantalum carbide, hafnium carbide, and combinations thereof. The layers of WFM are conformal layers which can be formed by a conformal deposition process such as, for example, ALD, CVD or PECVD. The layer of WFM layer can have a thickness in the range of approximately 1 nm to 20 nm, although other thicknesses above or below this range may be used as desired for a particular application.

As shown in FIG. 9A, an additional gate electrode material is formed on top of the topmost semiconductor layer 108 in each of the nanosheet stacks 103, and the additional gate electrode material layer may be considered to be part of the overall HKMG stack 130 structure. In certain embodiments, an optional material removal process, such as chemical mechanical planarization (CMP) may be performed to planarize the upper surface of the overall semiconductor device 100. The cross-sectional view of FIG. 9B is the same as FIG. 8B.

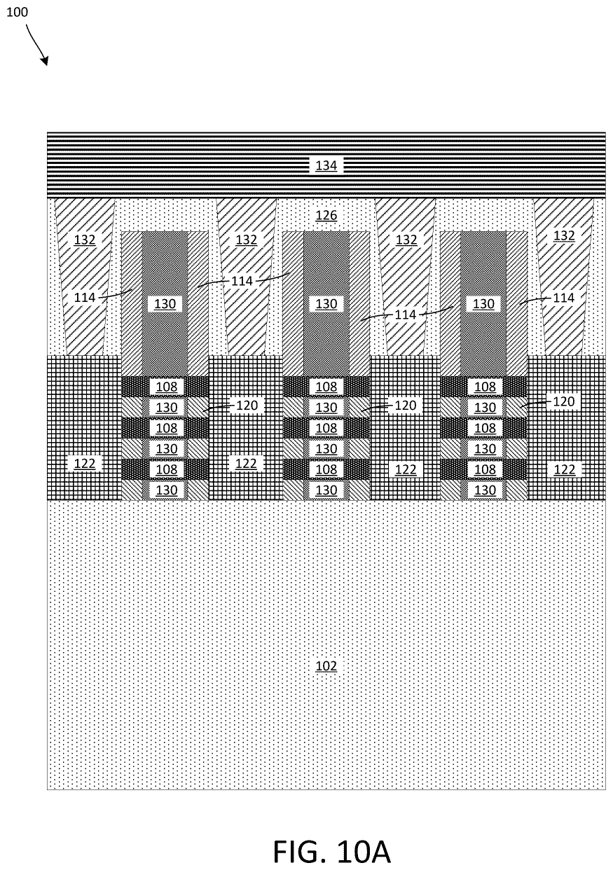

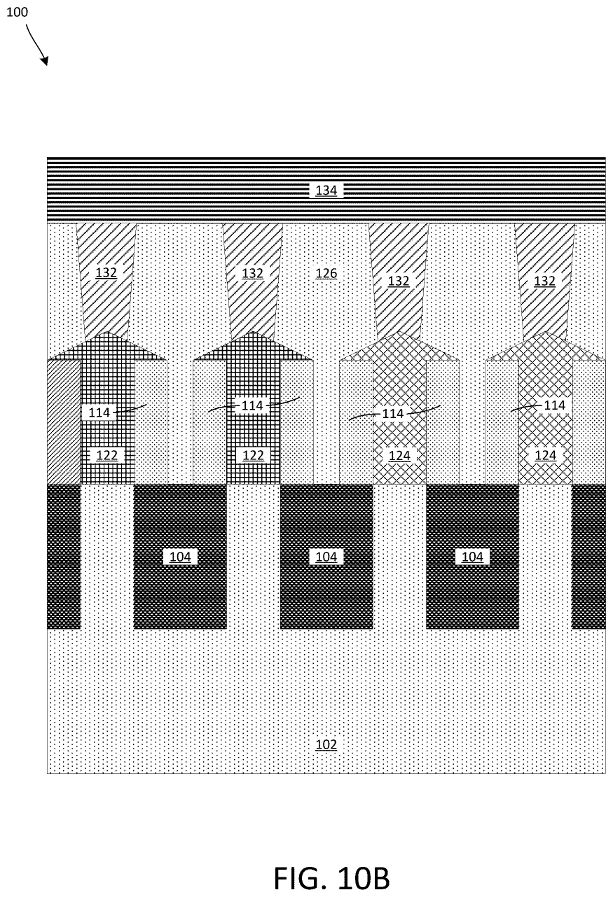

Referring now to FIG. 10A, this figure is a partial cross-sectional view of the semiconductor device 100 of FIG. 9A at a subsequent stage of the fabrication process and taken along the X1-X2 line of FIG. 1C, according to embodiments. Similarly, FIG. 10B is a partial cross-sectional view of the semiconductor device 100 of FIG. 9B at a subsequent stage of the fabrication process and taken along the Y1-Y2 line of FIG. 1C, according to embodiments. As shown in FIG. 10A, one or more suitable material removal processes are performed to form several contact openings (not shown) in the ILD layer 126. These material removal processes temporarily expose the top surfaces of the n-type source/drain epitaxial layers 122 (as shown in FIGS. 9A and 9B) and the top surfaces of the p-type source/drain epitaxial layers 124 (as shown in FIG. 9B). Then, several metal contacts 132 (sometimes referred to as contacts or abbreviated as CA) are formed in the spaces created by the previous removal of the portions of the ILD layer 126. In certain examples, these metal contacts 132 may be a part of a middle of line (MOL) layer. Then, as shown in FIGS. 10A and 10B, a back end of line (BEOL) layer 134 formed on the metal contacts 132 and on the ILD layer 126.

Thus, in the present embodiments, a semiconductor device is provided with a gate spacer trimming (or thinning) scheme that thins a portion of the spacer in the gate region while keeping the thickness of a portion of the spacer in the source/drain region the same, and this may help to address the issues discussed above. This may enable a robust source/drain confinement and improved canyon space between adjacent gates.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a gate electrode formed on a substrate;
a source/drain epitaxial layer formed on the substrate;
a gate spacer layer formed on sides of the gate electrode; and
a source/drain spacer layer formed on sides of the source/drain epitaxial layer,
wherein the source/drain spacer layer has a first width, and the gate spacer layer has a second width that is less than the first width.

2. The semiconductor device of claim 1, the first width of the source/drain spacer layer is about 5-8 nm, and the second width of the gate spacer layer is about 9-15 nm.

3. The semiconductor device of claim 1, further comprising an interlayer dielectric layer covering the gate spacer layer and the source/drain spacer layer.

4. The semiconductor device of claim 1, further comprising a metal contact formed in contact with the source/drain epitaxial layer.

5. The semiconductor device of claim 4, further comprising a back end of line (BEOL) layer and a middle of line (MOL) layer, wherein the metal contact is formed in the MOL layer.

6. The semiconductor device of claim 1, wherein the gate electrode includes a high-κ dielectric layer, and a work function metal layer in contact with the high-κ dielectric layer.

7. The semiconductor device of claim 1, wherein the gate electrode is formed as a nanosheet stack that includes alternating layers of a work function metal layer and a semiconductor layer.

8. The semiconductor device of claim 7, further comprising an inner spacer formed in contact with the work function metal layer.

9. The semiconductor device of claim 1, further comprising shallow trench isolation (STI) regions formed in the substrate.

10. The semiconductor device of claim 9, wherein the STI regions are formed under the source/drain spacer layer and between portions of the source/drain epitaxial layer.

11. An electronic device comprising:
a semiconductor device including
a gate electrode formed on a substrate;
a source/drain epitaxial layer formed on the substrate;
a gate spacer layer formed on sides of the gate electrode; and
a source/drain spacer layer formed on sides of the source/drain epitaxial layer,
wherein the source/drain spacer layer has a first width, and the gate spacer layer has a second width that is less than the first width.

12. The electronic device of claim 11, the first width of the source/drain spacer layer is about 5-8 nm, and the second width of the gate spacer layer is about 9-15 nm.

13. The electronic device of claim 11, further comprising an interlayer dielectric layer covering the gate spacer layer and the source/drain spacer layer.

14. The electronic device of claim 11, further comprising a metal contact formed in contact with the source/drain epitaxial layer.

15. The electronic device of claim 14, further comprising a back end of line (BEOL) layer and a middle of line (MOL) layer, wherein the metal contact is formed in the MOL layer.

16. The electronic device of claim 11, wherein the gate electrode includes a high-κ dielectric layer, and a work function metal layer in contact with the high-κ dielectric layer.

17. The electronic device of claim 11, wherein the gate electrode is formed as a nanosheet stack that includes alternating layers of a work function metal layer and a semiconductor layer.

18. The electronic device of claim 17, further comprising an inner spacer formed in contact with the work function metal layer.

19. The electronic device of claim 11, further comprising shallow trench isolation (STI) regions formed in the substrate.

20. The electronic device of claim 19, wherein the STI regions are formed under the source/drain spacer layer and between portions of the source/drain epitaxial layer.
